(19) United States
(12) Patent Application Publication
(10) Pub. No.: US 2006/0126306 A1
(43) Pub. Date: Jun. 15, 2006

(54) Multi-power optoelectric packages

(76) Inventors: Thomas H. Blair, San Jose, CA (US); William Lee Schmidt, Los Gatos, CA (US)

Correspondence Address: ROBERT A. PARSONS, 4000 N. CENTRAL AVENUE, SUITE 1220, PHOENIX, AZ, 85012, US

(21) Appl. No.: 10/406,325

(22) Filed: Apr. 3, 2003

Related U.S. Application Data
(60) Provisional application No. 60/370,169, filed on Apr. 5, 2002.

(51) Int. Cl. H05K 7/14; H05K 7/20; H05K 9/00

(52) U.S. Cl. 361/716; 361/730; 361/818; 361/712

(57) ABSTRACT

A cage assembly comprising a mounting rack with a plurality of adjacent openings wherein a width of each opening in the plurality of adjacent openings is capable of receiving a single width transceiver package, wherein each adjacent opening in the plurality of adjacent openings is capable of receiving a multi-width transceiver package, and wherein the width of the multi-width transceiver package is N times the width of the single width transceiver package wherein N is an integer number greater than one.

### CROSS-REFERENCE TO RELATED APPLICATION

This application claims the benefit of U.S. Provisional Application No. 60/370,169, filed 05 Apr. 2002.

### FIELD OF THE INVENTION

This invention relates to optical-to-electrical and electrical-to-optical (hereinafter “optoelectric”) or transceiver packages and more particularly to mounting apparatus for multi transceiver and multi-power packages.

### BACKGROUND OF THE INVENTION

At the present time, packages, containing one pair of optoelectric modules, are contained in one common or standard package. The modules are generally used in pairs for two-way communication and multiple pairs are incorporated in multiple packages nested in mounting racks to provide multiple communication channels. As the number of packages increases in a rack the amount of heat produced increases. Also, it is desirable to increase the operating power and/or the operating frequency, i.e., the amount of information conveyed, and to compensate for changes in optoelectric devices (e.g., lasers for conveying light over longer distances). Such increases in operating frequency or information conveyed substantially increase the operating power and, hence, the amount of power that must be dissipated by the package.

In prior art structures, the packages are constructed all the same size, regardless of the power consumption, and the standard size is designed to accommodate the maximum power consumption. For example, two different packages are generally offered commercially, a <6 watt package and a <10 watt package. Both of the packages are designed to accommodate the <10 watt power consumption. Since all of the packages are the same size and shape, a mounting rack is provided to nestingly accept either package in an opening surrounded by metal for EMI protection.

### BRIEF DESCRIPTION OF THE DRAWINGS

Referring to the drawings:

FIG. 1 is an isometric view of a prior art optoelectric multi-power package;

FIG. 2 is an isometric view of two low power optoelectric packages installed in adjacent positions in a common rack;

FIG. 3 is an isometric view of a single high power optoelectric package installed in a mounting rack with an adjacent thermoelectric cooling module, in accordance with the present invention;

FIG. 4 is an isometric view similar to FIG. 3 in which the thermoelectric cooling module is physically engaged with the high power optoelectric package;

FIG. 5 is an enlarged end view illustrating engaging surfaces of an embodiment of a thermoelectric cooling module and the high power optoelectric package;

FIG. 6 is a top view of the common rack illustrated in FIG. 2; and

FIG. 7 is a front view of the common rack illustrated in FIG. 2.

### DETAILED DESCRIPTION OF THE DRAWINGS

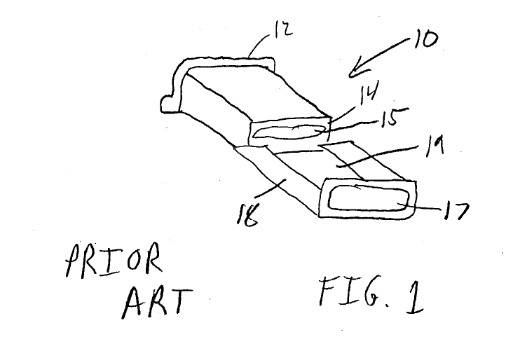

Turning now to FIG. 1, a prior art optoelectric multi-power package 10 is illustrated. Package 10 is commercially available as a hot-swappable, Z-axis pluggable, fiber optic transceiver. Further, package 10 is a 10 Gigabit structure and comes in two power dissipation versions, <6 watts and <10 watts. Both power dissipation versions are the same size, i.e., the length and surface area, with the size of the structures being determined by the higher power version. A front end 12 is designed to receive fiber optics for the transmission of light into and out of package 10 and a rear end 14 includes an electrical connector 15 designed to connect with an industry standard 70 pin electrical connector 17 mounted on a printed circuit board 18.

As can be seen in FIG. 1, printed circuit board 18 has a cut-out portion 19 designed to receive package 10 therein. Cut-out portion 19 is required to allow package 10 to extend above and below printed circuit board 18 for extra cooling. Cut-out portion 19 requires extra mounting efforts, including redesign of printed circuit boards, that are generally not desirable.

It will be understood that eight packages can be mounted on one 17″ printed circuit board when the <6 watt versions are used. However, only four packages can be mounted on a 17″ printed circuit board when the <10 watt version is used, due to the problem of total mass flow of air for that much power consumption.

However, it will also be understood that the dimensions of the packages, and, consequently, the number of packages that can be mounted on a printed circuit board will depend on the specified Multi-Source Agreement (hereinafter referred to as “MSA”). Typical MSA's include XENPAK, X2, XFP, SFP, SFF, or the like, and define electrical-, optical-, and mechanical-implementation specifications. MSA's are provided so that multiple module makers can provide components which are interchangeable and compatible.

Turning now to FIG. 2, two low power (e.g., each <6 watts) transceiver packages 20 and 22 are illustrated installed in a mounting rack 25. A top view of mounting rack 25 is illustrated in FIG. 6 and a front view is illustrated in FIG. 7. In a preferred embodiment, transceiver packages 20 and 22 are aligned in rack 25 by a plurality of guiding elements 21. In general, mounting rack 25 is designed to allow the installation of two or more transceiver packages in adjacent positions wherein a faceplate or front bezel 26 closes the opening to prevent electromagnetic interference (See FIG. 6).

Typically, transceiver packages 20 and 22 include openings 24 for receiving transmitter or receiver modules. In the preferred embodiment, modules 20 and 22 slide along guiding elements 21 and engage electrical connectors 23. Multi-position cage assemblies, similar to those described in copending U.S. patent application entitled “MULTI-POWER OPTOELECTRIC PACKAGES AND MOUNTING STRUCTURES”, filed of even date herewith, and incorporated herein by reference, can be used if desired.

In the above identified patent application, a cage assembly is disclosed that is capable of accepting transceiver packages of 1× (i.e. a single width), 2× (i.e. a double width), 3× (i.e. a triple width), 4× (a quadruple width), etc. widths. Also, the cage assembly does not include interior walls between 1× positions. Thus, for example, a 2× cage assembly has two 1× positions side-by-side and can receive two 1× transceiver modules or one 2× transceiver module. Similarly, a 3× cage assembly has three 1× positions side-by-side and can receive one 3× transceiver module, a 2× transceiver module and one 1× transceiver module, or three 1× transceiver modules (See FIG. 7).

It will be understood that the dimensions of the packages (i.e. modules 20 and 22), and, consequently, the number of packages that can be mounted on mounting rack 25 will depend on the specified Multi-Source Agreement (hereinafter referred to as “MSA”).

In accordance with the invention described in the above identified provisional application, single width (1×) transceiver packages can be designed, for example, to dissipate <6 watts. Double width (2×) transceiver packages can be designed, for example, to dissipate <10 watts. Triple width, quadruple width (3×, 4×, or multi-width) transceiver packages can be designed for even greater power dissipation. In each of these packages, the height and length remains constant but the width changes to accommodate a larger package for more power consumption. In other words, the width is generally proportional to the transceiver power dissipation. A more detailed description of multi-width packages is provided in a copending U.S. Patent Application entitled “MULTI-POWER OPTOELECTRIC PACKAGES”, Ser. No. 10/376,204, filed on 27 Feb. 2003, and incorporated herein by reference.

In the present embodiment, low power and high power transceiver packages can be constructed the same size and they can be designed smaller. For example, both of the transceiver packages can be designed to accommodate the lowest power (e.g., <6 watts) or some selected mid-power. When low power transceiver packages are used, they can be installed in adjacent positions, as illustrated in FIG. 2.

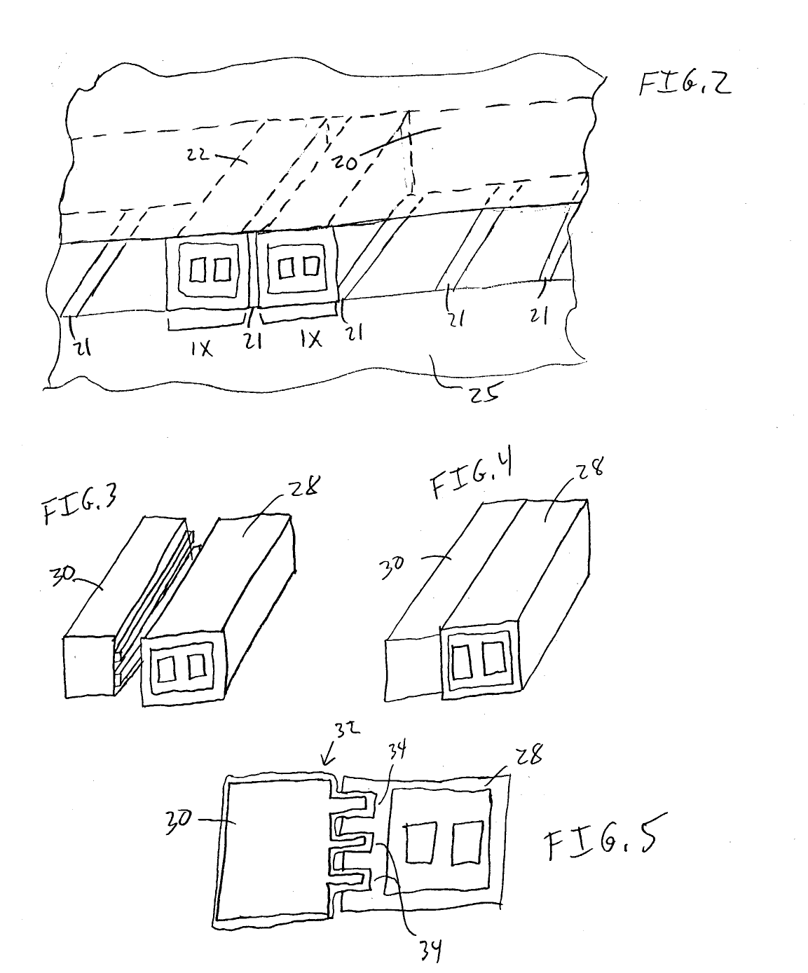

Referring additionally to FIG. 3, a high power transceiver package 28 is illustrated in the right hand slot, similar to transceiver package 20 in FIG. 1, and a thermoelectric cooling module 30 is positioned in an adjacent slot. In this preferred embodiment, the mounting rack is designed so that transceiver package 28 and thermoelectric cooling module 30 can be installed in a side-by-side relationship and thermoelectric cooling module 30 can then be moved into physical engagement with transceiver module 28, as illustrated in FIG. 4. Generally, it is preferred that thermoelectric cooling module 30 be movable, since transceiver module 28 usually plugs into connectors at the rear end of the mounting rack.

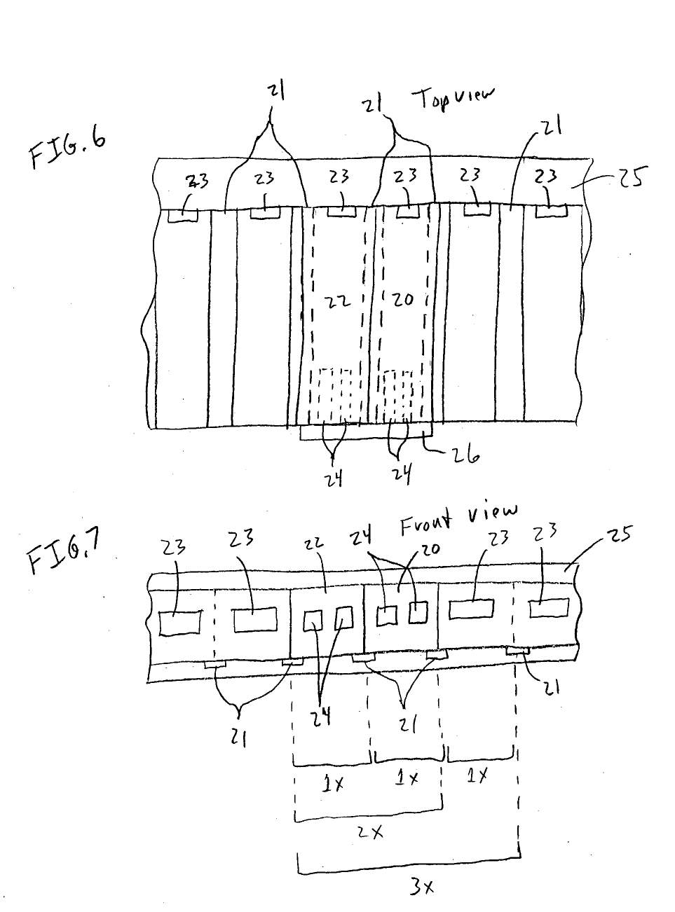

Referring additionally to FIG. 5, one embodiment for thermoelectric cooling module 30 is illustrated. In this embodiment, the side of thermoelectric cooling module 30 is constructed of a compliant springy material 32 that meshes into longitudinally extending slots 34 in the adjacent side of transceiver module 28. While longitudinally extending slots are illustrated for simplicity, it will be understood that vertical slots, horizontal slots, or any other convenient coupling elements could be utilized. In this fashion a positive thermal engagement is produced between transceiver package 28 and thermoelectric cooling module 30. Heat is transferred freely between transceiver package 28 and thermoelectric cooling module 30, which acts as a heat sink or provides additional heat transfer area.

Thus, transceiver package 28 can be constructed to include higher power components and it can still be constructed the same size as low power transceiver package 20. While <6 watts and <10 watts are used by way of example, it will be understood that the present invention can accommodate substantially any power variations, such as <1 watt versus <3 watts, <4 watts versus <6 watts, etc. Thus, the board density is improved.

By constructing different sized thermoelectric cooling modules a large variety of different power rated transceiver packages can be provided in one common sized package. Thermoelectric cooling module 30 can simply be a passive module that provides expanded heat transfer surface area. Thermoelectric cooling module 30 can also be an active module that contains, for example, a fan powered by the voltage pins of the slot it is plugged into. Diagnostic thermal management can be performed using the I²C interface of this slot.

Various changes and modifications to the embodiments herein chosen for purposes of illustration will readily occur to those skilled in the art. To the extent that such modifications and variations do not depart from the spirit of the invention, they are intended to be included within the scope thereof which is assessed only by a fair interpretation of the following claims.

Having fully described the invention in such clear and concise terms as to enable those skilled in the art to understand and practice the same, the invention claimed is:

1. A cage assembly comprising:
a mounting rack with a plurality of adjacent openings;
wherein a width of each opening in the plurality of adjacent openings is capable of receiving a single width transceiver package;
wherein the plurality of adjacent openings are capable of receiving a multi-width transceiver package; and
wherein the width of the multi-width transceiver package is N times the width of the single width transceiver package wherein N is an integer number greater than one.

2. A cage as claimed in claim 1 wherein at least one of a bezel and a faceplate is positioned over the plurality of adjacent openings to reduce electromagnetic interference.

3. A cage as claimed in claim 1 wherein the plurality of adjacent openings are capable of receiving at least one of two single width transceiver packages and one double width transceiver package.

4. A cage as claimed in claim 1 wherein the plurality of adjacent openings is capable of receiving at least one of a single width transceiver package, a double width transceiver package, a triple width transceiver package, and a quadruple width transceiver package.

5. A cage as claimed in claim 1 wherein the cage is capable of receiving at least one of a triple width transceiver package, three single width transceiver packages, and a double width and a single width transceiver package.

6. A cage as claimed in claim 1 wherein the width of each opening in the plurality of adjacent openings is chosen to be proportional to the power dissipation of the single width transceiver package.

7. A cage as claimed in claim 1 wherein the plurality of adjacent openings can receive a single width thermoelectric cooling module positioned adjacent to a transceiver module.

8. A cage as claimed in claim 7 wherein the thermoelectric cooling module is positioned in physical engagement with the adjacent transceiver module.

9. A cage as claimed in claim 8 wherein a side of the thermoelectric cooling module is constructed of a compliant springy material that meshes into slots in the adjacent side of the transceiver module.

10. A cage as claimed in claim 1 wherein each adjacent opening in the plurality of adjacent openings is separated by a guiding element.

11. A cage as claimed in claim 1 wherein the width of each opening in the plurality of adjacent openings is defined by a Multi-Source Agreement.

12. A cage assembly comprising:
a mounting rack with at least two adjacent openings;
wherein a width of each opening in the at least two adjacent openings is capable of receiving a single width transceiver package;
wherein the at least two adjacent openings are capable of receiving at least one multi-width transceiver package; and
wherein a width of the at least one multi-width transceiver package is N times the width of the single width transceiver package wherein N is an integer number greater than one.

13. A cage as claimed in claim 12 wherein at least one of a bezel and a faceplate is positioned over the at least two openings to reduce electromagnetic interference.

14. A cage as claimed in claim 12 wherein the at least two adjacent openings are capable of receiving at least one of one double width transceiver package and two single width transceiver packages.

15. A cage as claimed in claim 12 wherein the at least two adjacent openings are capable of receiving at least one of a single width transceiver package, a double width transceiver package, a triple width transceiver package, and a quadruple width transceiver package.

16. A cage as claimed in claim 12 wherein the at least two adjacent openings are capable of receiving at least one of a triple width transceiver package, three single width transceiver packages, and a double width and a single width transceiver package.

17. A cage as claimed in claim 12 wherein the width of the transceiver package is chosen to be proportional to the power dissipation.

18. A cage assembly comprising:
a mounting rack with an opening capable of receiving at least one multi-width transceiver module; and
wherein a width of the opening is N times the width of a single width transceiver module wherein N is an integer greater than one.

19. A cage as claimed in claim 18 wherein the width of the opening is chosen to be proportional to the power dissipation of the at least one multi-width transceiver module.

20. A cage as claimed in claim 18 wherein the width of the opening is determined by a Multi-Source Agreement.
